(19) United States
(12) Patent Application Publication
(10) Pub. No.: US 2025/0140701 A1
(43) Pub. Date: May 1, 2025

(54) POWER MODULE AND METHOD FOR PRODUCING A POWER MODULE

(71) Applicant: Robert Bosch GmbH, Stuttgart (DE)

(72) Inventor: Irfan Aydogmus, Nuertingen (DE)

(21) Appl. No.: 18/915,669

(22) Filed: Oct. 15, 2024

(30) Foreign Application Priority Data
Oct. 26, 2023 (DE) 10 2023 210 592.6

(51) Int. Cl. H01L 23/538; H01L 23/367; H01L 25/00; H01L 25/07

(52) U.S. Cl. CPC H01L 23/5383; H01L 23/3675; H01L 23/5386; H01L 25/071; H01L 25/50

(57) ABSTRACT

A power module. The power module has a first circuit carrier containing a carrier substrate, a first conductor structure with an external contact region, at least one second conductor structure with at least one external contact region, a further, third conductor structure includes an external contact region, a first group of semiconductor components and a second group of semiconductor components. A multifunctional frame is assigned to the power module, the groups of semiconductor components being arranged in a first level which is spatially separated from a second level in the multifunctional frame, in which contact faces contacting the groups of semiconductor components are accommodated.

### FIELD

The present invention relates to a power module with a first circuit carrier made of a carrier substrate and a first conductor structure with an external contact region, at least one second conductor structure with at least one external contact region, and a further, third conductor structure which comprises an external contact region, further with a first group of semiconductor components and a second group of semiconductor components. Furthermore, the present invention relates to a method for producing a power module.

### BACKGROUND INFORMATION

In the related art, power modules, which are installed in a power module bridge, for example, are additionally molded. During molding, the power module is embedded in a solid protective housing, for example made of plastic (molding compound). The molding compound is used to enclose and protect the interior of the power module. However, these enclosures of the power module by means of molding compound are not particularly resistant to cracks.

German Patent Application No. DE 11 2017 004 390 T5 describes a power module that has the following features: an insulating substrate with a front side to which a power semiconductor element is fastened; a base plate connected to a rear side of the insulating substrate; a housing fastened to the base plate and surrounding the insulating substrate; a cover fastened to the housing and forming a sealed region; and a silicone gel serving as a filling element which fills the entire sealed region and has an internal stress that acts as a compressive stress.

German Patent Application No. DE 10 2014 219 998 B4 describes a power module, in particular for providing a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the corresponding first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces. Furthermore, the power module comprises at least two third contact faces on the surface, wherein the at least two second power transistors each have a further contact face on their sides facing away from the surface of the circuit carrier, and in each case a second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each have a further contact face on their sides facing away from the surface of the circuit carrier, and in each case a first power transistor of the at least two first power transistors is electrically conductively connected via its further contact face to the in each case one contact region, located next to it, of the at least two contact regions of the second contact face. In this case, the at least two contact regions of the second contact face and the at least two second power transistors are arranged alternately one after the other in the longitudinal direction.

European Patent No. EP 2 418 925 B1 describes electrical contacting between a flexible film, which has at least one conductor track, and at least one electrical contact of a sensor device or control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

According to the present invention, a power module is provided which includes a first circuit carrier made of a carrier substrate, with a first conductor structure with an external contact region, at least one second conductor structure with at least one external contact region, and a further, third conductor structure which comprises an external contact region, with a first group of semiconductor components and a second group of semiconductor components. A multifunctional frame is assigned to the power module, the groups of semiconductor components being arranged in a first level which is spatially separated from a second level in the multifunctional frame, in which contact faces contacting the groups of semiconductor components are accommodated.

The solution proposed according to the present invention can provide an option for better cooling of the semiconductor components, since current-conducting paths can be relocated into the multifunctional frame and can be realized there either next to each other or one above the other, preferably in a low-inductance design, whereby switching losses can be reduced.

In an advantageous example embodiment of the power module proposed according to the present invention, the multifunctional frame is accommodated either above or below the power module, viewed in the Z direction. This allows for a greater degree of freedom in the layout of the power module.

In a further advantageous example embodiment of the power module proposed according to the present invention, current-conducting paths T+bridge and T−bridge are arranged one above the other or next to each other in the multifunctional frame, preferably with low inductance.

In a further advantageous example embodiment of the power module according to the present invention, the contact faces in the second level can be contacted by means of press-in pins. In this context, press-in pins represent a fairly robust contacting option and ensure a reliable electrical connection.

In a further advantageous example embodiment of the power module according to the present invention, the groups of semiconductor components arranged in the first level can also be contacted via press-in pins.

The power module proposed according to the present invention is further characterized in that the power module is connected to a cooling surface with its bottom side, either via a sintered connection or via a solder or adhesive connection. Both by forming a sintered connection and by forming a flat, materially bonded connection in the form of a solder or adhesive connection, a very good heat transfer and thus heat dissipation of the semiconductor components of the power module can be achieved.

In a further advantageous example embodiment of the power module proposed according to the present invention, the contact faces arranged in the second level of the multifunctional frame have openings which are located above the semiconductor components, arranged in the first level, of the groups of semiconductor components. This allows contact to be made in a substantially vertical direction.

In the power module proposed according to the present invention, the contact faces located in the second level are electrically connected to each of the semiconductor components arranged in the first level, for example via L-parts.

This connection option, which runs substantially in a vertical direction, enables an electrically conductive connection to be achieved between the first level and the second level of the arrangement made up of the power module and the multifunctional frame.

In a further advantageous realization of this variant embodiment of the present invention, a spacer is arranged between the L-parts and a contact face of the semiconductor element. By using the spacer, different installation heights or resulting tolerances can be easily compensated. By using one or more spacers, the energy input during welding of the upper joining partners to the contact face of the semiconductor components, for example MOSFETs, transistors, GBDTs, or diodes, can be reduced, and melting can be effectively prevented.

As an alternative to the use of L-parts, the power module proposed according to the present invention can provide for a materially bonded connection between the multifunctional frame in the second level and the semiconductor components, arranged in the first level, of the group of semiconductor components.

This is preferably carried out within an opening of the multifunctional frame as a welded connection, for example on a joining partner, in particular a flat copper layer.

Furthermore, the present invention relates to a method for producing a power module, in which
a first conductor structure with a first contact region,
at least one second conductor structure with at least one external contact region, and
a further, third conductor structure with an external contact region are provided, wherein
a multifunctional frame is assigned to the power module,
groups of semiconductor components are arranged in a first level, which are arranged spatially separated from a second level in the multifunctional frame,
wherein contact faces contacting the groups of semiconductor components are arranged in the second level.

The solution proposed according to the present invention allows the decoupling and spatial separation of current-conducting surfaces and semiconductor components that produce heat during operation, which can be MOSFETs, transistors, or semiconductor switches, or the like.

By means of the power module proposed according to the present invention or its inventive design, active surfaces and layout surfaces can be separated from one another. Due to the arrangement of the multifunctional frame proposed according to the present invention, which is arranged for example above the power module, the current flow is relocated from the power module to the multifunctional frame arranged above it. This results in an improved cooling option for the semiconductor components. These can be transistors, flip-flops, MOSFETs, or the like. The solution proposed according to the present invention enables improved cooling to be achieved, since larger distances between the semiconductor components can be realized. The solution proposed according to the present invention makes it possible to relocate current-conducting paths, such as T+bridge and/or T−bridge, into the multifunctional frame and to realize them there one above the other or next to each other with low inductance. In particular, the possibility of designing the current-conducting paths as low-inductance current paths reduces switching losses that occur.

The decoupling of the first and second levels in the power module and multifunctional frame results in a compact design of the power module proposed according to the present invention. Furthermore, the selected superimposed arrangement of the two functional levels, namely the first level in which the semiconductor components are arranged and the second level in which the current is conducted, can significantly improve production and also increase the service life of the power module because its complexity is significantly reduced.

In particular, if the contacting of the semiconductor components in the first level and that of the current-conducting contact faces in the second level, i.e., within the multifunctional frame, is represented by press-in pins, a robust electrical contacting option for the aforementioned components is achieved. Furthermore, the design of press-in pins is technically proven and they can be robustly produced on a large scale.

Further following the solution proposed according to the present invention, the bottom side of the power module can advantageously be connected to the top side of a cooling surface either by a flat sintered connection or by a flat solder connection or by a flat adhesive connection. All design variants offer the advantage of flat contacting, which allows the waste heat generated during operation of the semiconductor components of the power module to be reliably dissipated, and no temperature overloading of the power module proposed according to the present invention occurs.

Following the solution proposed according to the present invention, the external contact regions of the power module are displaced in the vertical direction, i.e., in the Z direction, and are provided in the multifunctional frame. This makes it possible to spatially decouple the semiconductor components from the current-conducting paths or the external contact faces, so that the total available area, i.e., the chip surface, can be better utilized or made considerably smaller, thereby significantly saving costs. If the T+bridge and the T−bridge are realized so as to be coplanar one over the other with a minimized distance in the Z direction, the magnetic fields generated by the current flow in these components are canceled, so that parasitic effects of the current are largely excluded and a low-inductance connection can be achieved. The solution proposed according to the present invention considerably simplifies the complexity of the power module and of the entire assembly, including the multifunctional frame. By shifting the multifunctional frame in the Z direction, whether above or below the power module, a spatial decoupling can be achieved, depending on the available installation space requirements. By using press-fit pins, a standardized interface for signal transmission can be achieved, as well as for the line contacts. Furthermore, it is possible to arrange the semiconductor components in groups, for example to form a group with six semiconductor components, or to arrange the number with 12, 8, or 4 semiconductor components depending on the requirements and variants, while maintaining appropriate distances on the base surface of the power module. The solution proposed according to the present invention enables very small tolerances to be maintained for subsequent connection and installation processes. Overall, the reliability of the power module with the multifunctional frame assigned to it can be significantly improved due to the substantially better heat dissipation, which, not least, is beneficial for its service life. The inductive connection of the semiconductor components enables very short switching times of the semiconductor components.

### BRIEF DESCRIPTION OF THE DRAWINGS

The present invention is described in more detail below with reference to the figures.

FIG. 1 shows a plan view of a first circuit carrier of a power module comprising a carrier substrate and a possible arrangement of semiconductor switches, according to an example embodiment of the present invention.

FIG. 2 shows a plan view of a power module with separate cooling and layout areas with laterally arranged regions for press-in pins, according to an example embodiment of the present invention.

FIG. 3 shows an arrangement of a power module mounted on a cooling surface and a multifunctional frame arranged above it in the Z direction, according to an example embodiment of the present invention.

FIG. 4 shows a perspective plan view of the arrangement according to FIG. 3.

FIG. 5 shows an enlarged view of a contacting of semiconductor components via L-parts and a connection of the power module to the cooling surface designed as a sintered connection, according to an example embodiment of the present invention.

FIG. 6 shows a representation according to FIG. 5, wherein the connection from the power module to the cooling surface is shown via a flat solder or adhesive connection, according to an example embodiment of the present invention.

FIG. 7 shows an alternative option for contacting semiconductor components via materially bonded connections with an interposition of a copper layer, according to an example embodiment of the present invention.

FIG. 8 shows a perspective view of the press-in pins protruding from the multifunctional frame, representing a standardized interface, according to an example embodiment of the present invention.

FIG. 9 shows an exploded view of the components of the multifunctional frame, according to an example embodiment of the present invention.

FIG. 10 shows a longitudinal section through the representation according to FIG. 8 with L-parts contacting each of the contact faces of the semiconductor components.

FIG. 11 shows the plan view of a power module bridge, accommodated on a cooling surface of a cooling device, according to an example embodiment of the present invention.

FIG. 12 shows a variant installation of the assembly, comprising the power module bridge according to FIG. 11 and the cooling device, accommodated on the top side of a battery system.

### DETAILED DESCRIPTION OF EXAMPLE EMBODIMENTS

In the following description of the embodiments of the present invention, identical or similar elements are denoted by the same reference signs, a repeated description of these elements in individual cases being dispensed with. The drawings show the subject matter of the present invention only schematically.

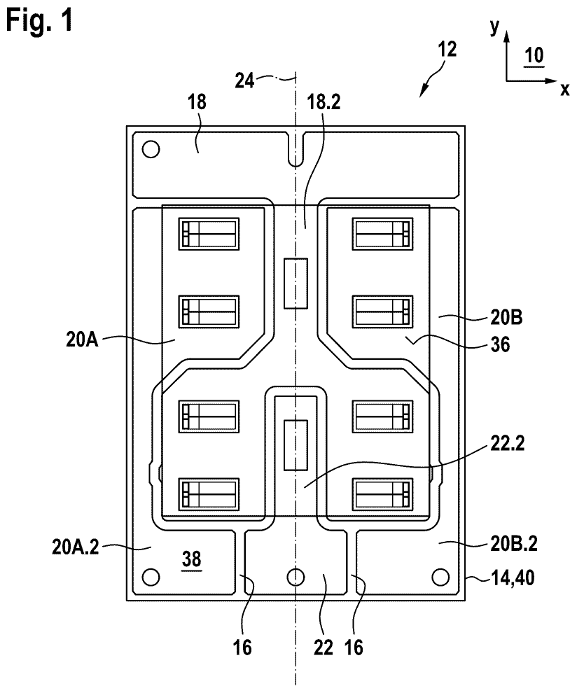

FIG. 1 shows a plan view of a power module 12, in particular its first circuit carrier 14.

From the plan view according to FIG. 1, it can be seen that a carrier substrate 40 of the first circuit carrier 14 is provided with a number of conductor structures 18, 20A, 20B, 22. The circuit carrier 14 extends in an X, Y plane 10, wherein the circuit carrier 14 is provided with an electrical insulation layer 16. On this layer, separated from each other by channel-shaped interruptions, there is a first conductor structure 18 which has an external contact region 18.2. Furthermore, second conductor structures 20A, 20B are located opposite one another on the first circuit carrier 14, symmetrically to a central longitudinal axis 24 of the power module 12. Each of the two second conductor structures 20A, 20B comprises an external contact region 20A.2, 20B.2. Finally, a third conductor structure 22, which has at least one external contact region 22.2, is applied to the first circuit carrier 14 or to its electrical insulation layer 16.

The aforementioned conductor structures 18, 20A, 20B, 22 are electrically separated from one another and are applied to the first circuit carrier 14 substantially symmetrically to the central longitudinal axis 24. Position 36 designates an active surface, and a layout surface surrounding it for the current routing is designated by reference sign 38. As the carrier substrate 40 of the first circuit carrier 14, AMB (active metal brazing) containing OFC (oxygen-free copper)/Si₃N₄/OFC can for example be selected.

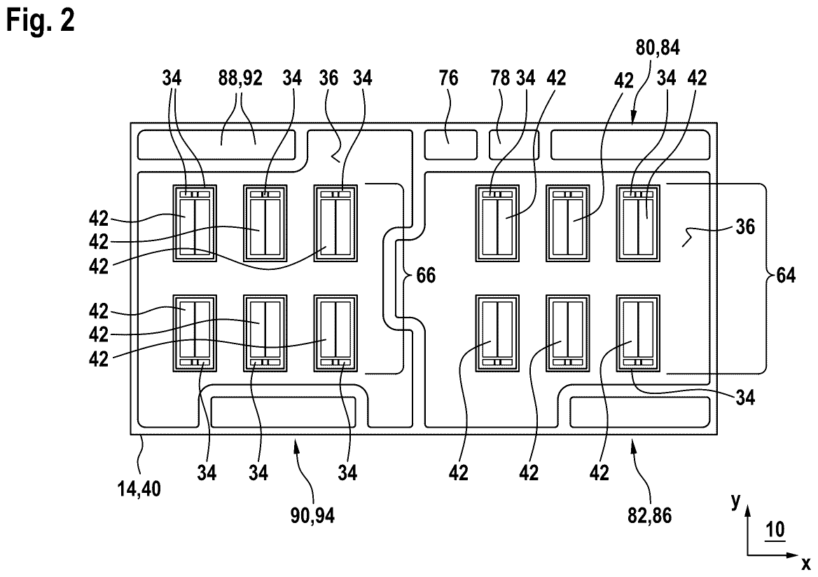

The illustration according to FIG. 2 shows a plan view of the power module 12, wherein in this schematic illustration semiconductor components 42 are arranged on active surfaces 36, which components may be for example transistors, MOSFETs, or other semiconductor components that can be used as semiconductor switches. FIG. 2 shows that a first group 64 of semiconductor components 42 is accommodated on the active surfaces 36. The individual semiconductor components 42 can be designed, for example, as MOSFETs and have control terminals 34 on their outer sides, via which a controlling (not shown in more detail) of the individual semiconductor components 42 of the first group 64 of semiconductor components 42 can take place. Analogous to the first group 64, a second group 66 of semiconductor components 42 is arranged, which can also be MOSFETs, on the outer region of each of which control terminals 34 are formed. The semiconductor components 42 of the second group 66 of semiconductor components 42 can be controlled from the outside via the control connections 34, although this is not shown in more detail in the illustration in FIG. 2.

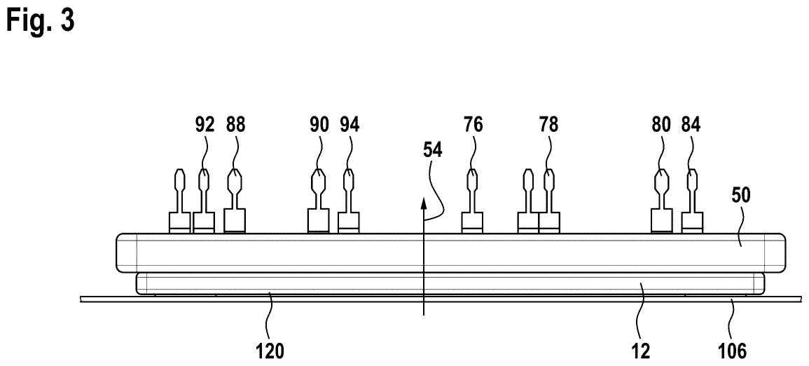

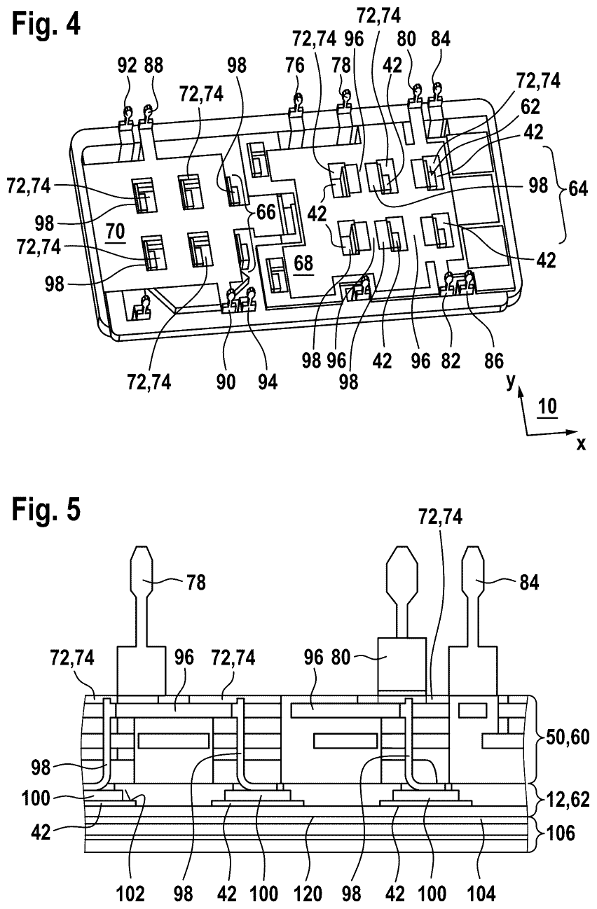

Furthermore, it can be seen from the plan view according to FIG. 2 that in the X, Y plane 10 shown in FIG. 2, regions are provided on the longitudinal sides of the first circuit carrier 14 in the form of a carrier substrate 40, in which regions press-in pins 76-94 protrude into the plane of the drawing according to FIG. 2. Specifically, these are first and second press-in pins 76, 78 as well as third and fourth press-in pins 80, 82 and, arranged opposite one another, fifth and sixth press-in pins 84, 86. In the region of the opposite end face of the first circuit carrier 14, seventh and eighth press-in pins 88, 90 are provided, as well as ninth and tenth press-in pins 92, 94. The spatial arrangement of the press-in pins 76, 78, 80, 82, 84, 86, 88, 90, 92, 94 can be seen in more detail in the illustrations in FIGS. 3 and 4.

In the side view according to FIG. 3, it can be seen that a power module 12, shown here from the outside, is received with its bottom side 120 on a cooling surface 106. Viewed in the Z direction 54, a multifunctional frame 50 is located above the power module 12. On the top side of the multifunctional frame 50 shown from the side in FIG. 3, the individual press-in pins 76, 78, 80, 82, 84, 86, 88, 90, 92, 94-here lying in a drawing plane-protrude vertically upwards. The press-in pins allow the within the multifunctional frame 50 or within the power module 12 arranged underneath to be electrically contacted in a robust and simple manner.

FIG. 4 shows a partial perspective view from the top side of the arrangement shown from the side in FIG. 3, made up of the multifunctional frame 50, the power module 12, and the cooling surface 106 arranged underneath. FIG. 4 shows that the first group 64 of semiconductor components 42 and the second group 66 of semiconductor components 42 are arranged in a first level 60 which runs substantially along the base of the power module 12. The arrangement pattern according to FIG. 4 substantially corresponds to the plan view shown in FIG. 2. From the illustration according to FIG. 4 it can be seen that substantially flat contact faces 68, 70 extend in a second level 62 that extends above the first level 60. The contact faces 68, 70 are preferably T+bridges 134 or T−bridges 138, which are described in more detail below, as well as a phase bridge 136. While the first contact face 68 has the third press-in pin 80 and, opposite thereto, the fourth press-in pin 82, the seventh press-in pin 88 is arranged on the second contact face 70 and the eighth press-in pin 90 is arranged laterally offset from the seventh pin.

From the illustration according to FIG. 4 it is further apparent that the semiconductor components 42, arranged below the second level 62, i.e. in the first level 60, of the first group 64 and of the second group 66 can be contacted via the press-in pins 84, 86, 92, 90. The arrangement or spatial decoupling of the levels 60, 62 shown in FIG. 4 makes it possible to achieve a compact design and a considerable improvement in the cooling of the semiconductor components 42, which produce waste heat during operation.

FIG. 4 further shows that the substantially flat contact faces 68, 70 are each formed with a number of openings 72, which in the embodiment of the contact faces 68, 70 according to FIG. 4 have a rectangular shape 74. As an alternative to the rectangular shape 74, another geometry, for example square or circular, is of course also possible for the geometry of the openings 72. Below the openings 72 formed in the surface of each of the contact faces 68, 70, a semiconductor component 42 is correspondingly situated. This means that the openings 72 located in the first level 60 are aligned with the positions of the semiconductor components 42 located in the second level 62 below it. As can also be seen from FIG. 4, for example the semiconductor components 42 of the first group 64 are electrically contacted via L-parts 98. The L-part 98 partially overlaps the edge of the opening 72, extends substantially in the vertical direction to the second level 62 arranged below the first level 60, and there extends up to the semiconductor component 42 positioned below the opening 72. The use of the L-parts 98 as current-transmitting elements enables a spatial separation in the Z direction 54, as indicated in connection with FIG. 3.

The same holds for the semiconductor components 42 of the second group 66 of semiconductor components 42, which are also accommodated in the first level 60 on the base of the power module 12.

The semiconductor components 42 of the second group 66 are also contacted by L-parts 98 which extend substantially in a vertical direction starting from the second level 62 in the direction of the first level 60, i.e. in the direction of the bottom of the power module 12. In the embodiment shown in FIG. 4, the contact faces 68, 70, which run in the second level 62 within the multifunctional frame 50, over which extend substantially in the vertical direction, i.e. in the opposite Z direction 54, are therefore contacted with the semiconductor components 42 arranged in the first level 60 on the base of the power module 12.

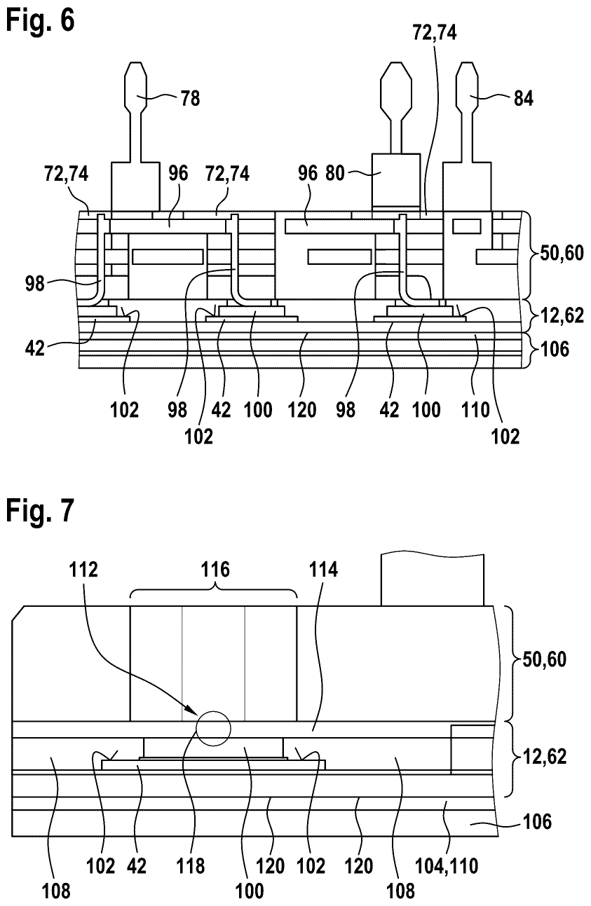

In the illustrations according to FIGS. 5 and 6, enlarged views of the L-parts 98 are shown. In the background of FIG. 5, here the second press-in pin 78, the third press-in pin 80 and the fifth press-in pin 84 are shown (enlarged), which are located behind the plane of the drawing in FIG. 5. From FIG. 5 it can be seen that the L-parts 98 extend through the openings 72, designed here in a rectangular shape 74, on both sides of the web 96 in the material of the first contact face 68. These L-parts extend through the openings 72 and contact, with their bent short side, a spacer 100 which in turn contacts a contact face 102 on the top side of the semiconductor component 42. In the illustration according to FIG. 5, a bottom side 120 of the power module 12 is connected via a flat sintered connection 104 to an underlying, substantially flat cooling surface 106. The waste heat generated during operation of the semiconductor components 42 can be effectively dissipated to a heat sink via the cooling surface 106 with the interposition of the sintered connection 104.

FIG. 6 substantially corresponds to the arrangement according to FIG. 5, with the multifunctional frame 50 arranged above the power module 12 and the webs 96, which are part of the first contact face 68. Starting from these, the L-parts 98 run in the direction of the spacers 100 and contact the contact face 102 on the top side of the semiconductor components 42. Differing from the variant embodiment of the power module 12 with the multifunctional frame 50 arranged on top according to FIG. 5, in the illustration of FIG. 6 the bottom side 120 of the power module 12 is connected to the cooling surface 106 arranged underneath it via a flat solder/adhesive connection 110. In other respects, the representations according to FIGS. 5 and 6 substantially correspond to each other. By contacting the bottom side 120 with the cooling surface 106, whether via a sintered connection 104 according to FIG. 5 or via a solder/adhesive connection 110 according to FIG. 6, waste heat generated during operation of the semiconductor components 42 is transported to a heat sink and dissipated, so that no excessive temperatures occur during operation of the power module 12.

FIG. 7 shows an alternative contacting option of the semiconductor components 42. Openings 116 are included in the multifunctional frame 50. The openings 116 are covered by a copper layer 114 on the bottom side of the multifunctional frame 50. A welded connection 118 is formed therein within a welding region 112, so that the chip (i.e. the semiconductor component 42) arranged beneath the copper layer 114, optionally with the interposition of the spacer 100, is electrically contacted. The spacer 100 located under the copper layer 114 and the semiconductor component 42 can be enclosed by a molding compound 108 or embedded therein. On the bottom side 120 of the power module 12, this module is connected via the sintered connection 104, analogous to the illustration of FIG. 5, or via a solder/adhesive connection 110, analogous to the embodiment of FIG. 6, to a substantially flat cooling surface 106 for dissipating the waste heat generated during operation of the semiconductor components 42.

In a method according to the present invention for producing the power module 12, a first conductor structure 18 with an external contact region 18.2, at least one second conductor structure 20A, 20B with at least one external contact region 20A.2, 20B.2, and a further third conductor structure 22 which has an external contact region 22 are provided on the power module. The multifunctional frame 50 is assigned to the power module 12; groups 64, 66 of semiconductor components 42 are arranged in a first level 60, which are spatially separated from a second level 62 in the multifunctional frame 50. Finally, current-conducting contact faces 68, 70 contacting the first and second groups 64, 66 of semiconductor components 42 are arranged in the second level 62.

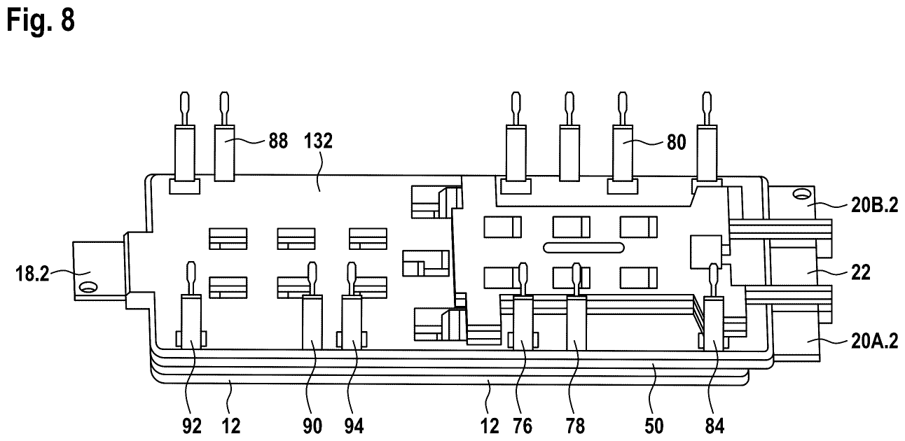

FIG. 8 shows a perspective plan view of a multifunctional frame 50 which is arranged above the power module 12, seen in the Z direction 54. From the plan view, it can be seen that a number of press-in pins 76, 78, 80, 84, 88, 92, 94 for electrical contacting or signal transmission protrude from the top of the multifunctional frame 50 made of plastics material 132. The external contact regions 18.2, 20A, 22B.2 and 22.2 for electrical contacting, which are relocated in the level of the multifunctional frame 50, protrude from the short end faces of the frame. In the perspective plan view of the power module 12 shown in FIG. 8, the multifunctional frame 50 is arranged above the power module 12, seen in the Z direction 54. However, the multifunctional frame 50 could also be arranged below the power module 12 or next to it in the Z direction 54, depending on the installation space requirements.

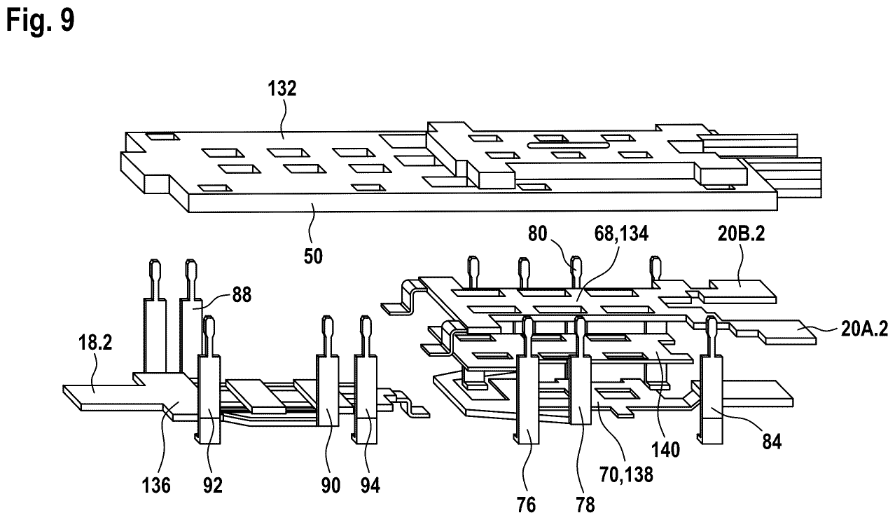

FIG. 9 shows an exploded view of the components housed in the multifunctional frame 50. These components are, in particular, relatively flat contact faces in the form of a T+bridge 134, a phase bridge 136, and a T−bridge 138. The T+bridge 134 and the T−bridge 138, arranged in coplanar fashion one over the other, are separated from each other by an insulation layer 140 made of paper or cardboard. By maintaining a small distance between the T+bridge 134 and the T−bridge 138, the magnetic fields generated by the current flow can be eliminated, i.e. they cancel each other out. This allows parasitic effects of the flowing current to be minimized and the connection to be realized with low inductance. A low-inductance connection leads to particularly short switching times for electrical semiconductor components, which is extremely advantageous for inverters or power electronics for electric drives of electrically powered vehicles.

As can be further seen from the exploded view in FIG. 9, the external contact regions 18.2, 20.2, 20B2 are also shown.

The phase bridge 136 can be contacted via the seventh press-in pin 88 and the eighth press-in pin 90. The other press-in pins, for example 92 and 94, protrude into the level arranged below the phase bridge 136, i.e. in the direction of the bottom 144 of the power module 12.

In an analogous manner, further press-in pins 76, 78, 80, 84 are assigned to the current-conducting T+bridge 134 or the T−bridge 138, which pins are used for electrical contacting and/or signal transmission.

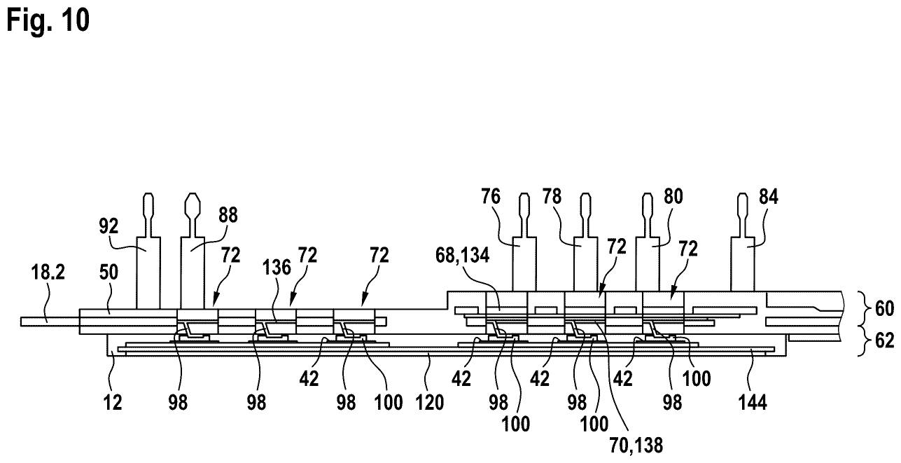

The illustration in FIG. 10 shows a section through the arrangement in FIG. 8. From the illustration according to FIG. 10 it can be seen that, for example, starting from the phase bridge 136, L-parts 98 are punched out in a vertical direction downwards, protrude into the second level 62, formed by the base surface 144 of the power module 12, and contact the semiconductor components 42 arranged there individually or in groups on their top side. The contact can in particular be designed as a materially bonded connection, preferably as a welded connection. The same applies to the T−bridge 138, which also represents a current-conducting, second contact face 70. From this face, L-parts 98 are bent downwards in a vertical direction within openings 72 of the multifunctional frame 50 and contact the contact faces 102 of the semiconductor components 42, optionally with the interposition of one or more spacers 100. These components are arranged individually or in groups 62, 64 on the base surface 144 of the power module 12, and can be cooled by a cooling device 158 or a cooling surface 106, described below.

The illustration in FIG. 10 further shows the coplanar arrangement of the T+bridge 134, which represents the first current-conducting contact face 68, and the T−bridge 138, which represents the second current-conducting contact face 70. The smaller the distance between these two components can be kept, the more favorable a cancellation of the magnetic fields can be achieved in the case of current flow, so that a low-inductance connection of the semiconductor components 42, which are arranged in the second level 62, i.e., below the multifunctional frame 50 representing the first level 60. For completeness, press-in pins 76, 78, 80, 84, 88, 92 are shown analogously to FIG. 8. The bottom side 120 of the power module 12 is cooled via a cooling device 158 which has a cooling surface 106.

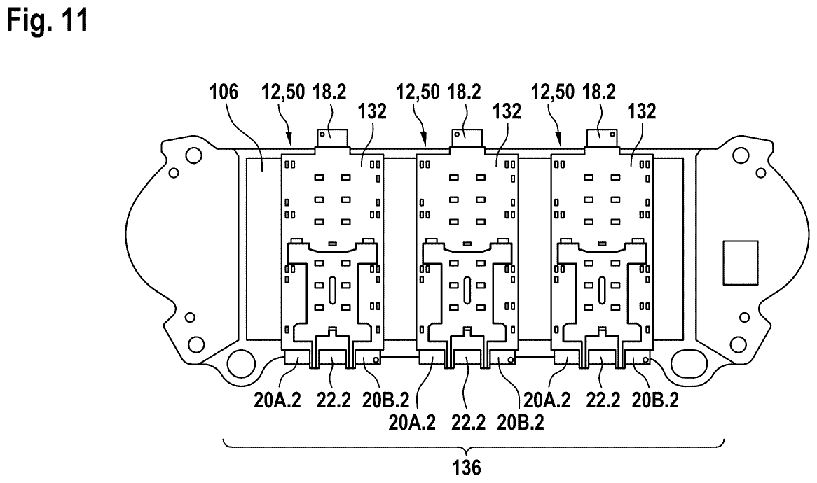

FIG. 11 shows a power module bridge 156 which comprises a number of power modules 12 on a cooling surface 106, with multifunctional frames 50 made of the plastics material 132 arranged and equipped above each of them. The individual power modules 12 with the multifunctional frames 50 assigned to each of them are arranged next to one another on the cooling surface 106 while maintaining a slight distance between them. The external contact regions 18.2, 22A.2, 22.2, and 22. B2 protrude beyond the short end faces of the power modules 12 for electrical contacting.

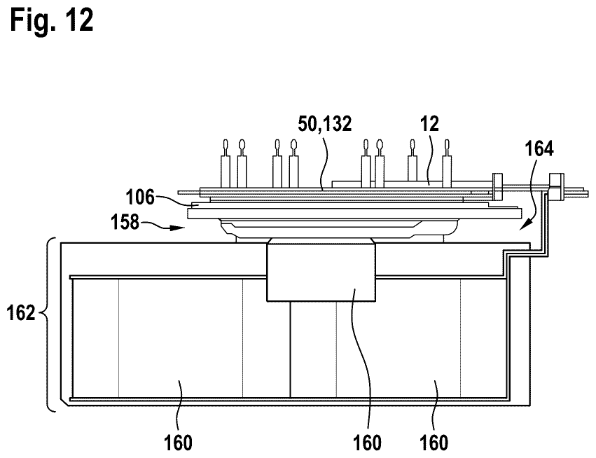

FIG. 12 shows that the cooling surface 106 is arranged on the top side of a cooling device 158 which is only arranged schematically here. This cooling device can be designed for example via suitable connections and lines 166 such that a cooling medium continuously flows through it, so that the bottom side of the power modules 12 arranged on the cooling surface 106 can be continuously cooled. This allows the waste heat that continuously arises during operation of the semiconductor components 42, which are arranged on the base 144 of the power module 12, to be effectively dissipated. From the illustration in FIG. 12 it can be seen that in this embodiment the arrangement of semiconductor component 42, multifunctional frame 50, and cooling device 158 is arranged as a connection 164 on the top side of the battery system 162. Of this, for simplicity only a few battery cells 160 are shown.

The present invention is not limited to the embodiments described here and the aspects emphasized therein. Rather, a large number of modifications are possible within the range of the present invention, which are within the scope of the activities of a person skilled in the art.

1-12 (canceled)

13. A power module, comprising:
a first circuit carrier containing a carrier substrate and a first conductor structure with an external contact region, at least one second conductor structure with at least one external contact region, and a further, third conductor structure which includes an external contact region, and a first group of semiconductor components and a second group of semiconductor components;
wherein a multifunctional frame is assigned to the power module, wherein the first and second groups of semiconductor components are arranged in a first level, which is spatially separated from a second level in the multifunctional frame, in which contact faces contacting the first and second groups of semiconductor components are accommodated.

14. The power module according to claim 13, wherein the multifunctional frame is arranged above or below the power module, seen in a Z direction.

15. The power module according to claim 13, wherein current-conducting paths are configured as a T+bridge, a T−bridge, and a phase bridge, arranged one above the other or next to each other in the multifunctional frame, with low inductance.

16. The power module according to claim 13, wherein the contact faces in the second level can be contacted using press-in pins.

17. The power module according to claim 13, wherein the first and second groups of semiconductor components arranged in the first level can be contacted via press-in pins.

18. The power module according to claim 13, wherein the power module is connected to a cooling surface with a bottom side of the power module, either via a sintered connection or via a solder or adhesive connection.

19. The power module according to claim 13, wherein the contact faces arranged in the second level of the multifunctional frame have openings which are located above the semiconductor components, arranged in the first level, of the first and second groups of semiconductor components.

20. The power module according to claim 19, wherein the contact faces of the second level are contacted with the semiconductor components arranged in the first level via L-parts.

21. The power module according to claim 20, wherein a spacer is arranged between the L-parts and a contact face of a semiconductor component.

22. The power module according to claim 19, wherein a materially bonded connection is made between the multifunctional frame in the second level and the semiconductor components of the first group of semiconductor components.

23. The power module according to claim 22, wherein the materially bonded connection within an opening is configured as a welded connection on a copper layer.

24. A method for producing a power module, comprising:
providing a first conductor structure with a first contact region, at least one second conductor structure with at least one external contact region, and a further, third conductor structure having an external contact region;
assigning a multifunctional frame to the power module;
arranging groups of semiconductor components in a first level of the multifunctional frame, which are spatially separated from a second level in the multifunctional frame; and
arranging contact faces contacting the groups of semiconductor components in the second level of the multifunctional frame.
